(19) United States
(12) Patent Application Publication
(10) Pub. No.: US 2007/0009838 A1
(43) Pub. Date: Jan. 11, 2007

(54) Method of manufacturing a pattern structure and method of forming a trench using the same

(75) Inventors: Ji-Yong You, Suwon-si (KR); Chun-Suk Suh, Yongin-si (KR); Hak Kim, Yongin-si (KR); Dae-Joung Kim, Suwon-si (KR); Kyoung-Yun Baek, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/475,913

(22) Filed: Jun. 28, 2006

(30) Foreign Application Priority Data
Jul. 7, 2005 (KR) 2005-61028

(51) Int. Cl. G03F 7/26

(52) U.S. Cl. 430/313; 430/311

(57) ABSTRACT

A method of manufacturing a pattern structure and a method of forming a trench using the same are provided. A mask pattern structure having mask patterns spaced apart from one another may be formed on a layer. The mask pattern structure may be divided into a first region having a first pattern density and a second region having a second pattern density higher than the first pattern density. The layer may be etched using the mask pattern structure as an etching mask to form first sidewalls positioned under the first region and second sidewalls positioned under the second region. The first sidewall may have a first profile that may be substantially vertical. The second sidewall may have a second profile of which an interval between the second sidewalls becomes narrower toward lower portions of the second sidewalls.

### PRIORITY STATEMENT

This application claims benefit of priority under 35 U.S.C. § 119 from Korean Patent Application No. 2005-61028, filed on Jul. 7, 2005, in the Korean Intellectual Property Office, the disclosure of which is incorporated herein by reference in its entirety.

### BACKGROUND OF THE INVENTION

1. Field of the Invention

Example embodiments of the present invention relate to a method of manufacturing a pattern structure and a method of forming a trench using the method of manufacturing the pattern structure. Other example embodiments of the present invention relate to a method of manufacturing a pattern structure formed by etching a layer and a method of forming a trench using the same.

2. Description of the Related Art

Semiconductor devices may be manufactured by performing a fabricating process for forming an electrical circuit on a substrate (e.g., a silicon wafer), an electrical die sorting (EDS) process for testing electrical characteristics of the semiconductor devices after the fabricating process and/or a package process for packaging the semiconductor devices using an epoxy resin after separating the wafer into individual chips.

The fabricating process may include a depositing process for forming a layer on a wafer, a chemical mechanical polishing process for planarizing a surface of the layer, a photolithography process for forming a photoresist pattern on the layer, an etching process for forming a pattern having electrical characteristics in, or on, the surface of the layer using the photoresist pattern as a mask pattern, an implantation process for implanting ions into designated areas of the wafer, a cleaning process for removing particles from the wafer, a drying process for drying the wafer after the cleaning process and/or a testing process for detecting defects of the layer and/or the pattern.

The photolithography process may include a coating process, a soft bake process, an exposure process, a development process and/or a hard bake process. The coating process may be performed to coat a semiconductor substrate with a photoresist composition. A photoresist film may be formed on the semiconductor substrate. The soft bake process may be performed to evaporate, or volatilize, a solvent included in the photoresist film. The exposure process and/or the development process may be performed to partially remove the photoresist film to form a photoresist pattern structure. The hard bake process may be performed to harden the photoresist pattern structure.

The layer under the photoresist pattern may be etched by using the photoresist pattern structure as an etching mask to form a pattern structure.

In general, the photoresist pattern structure may include photoresist patterns. The photoresist patterns may be spaced apart from one another. The photoresist pattern structure may be divided into a first region and a second region. A pattern density of the first region may be larger than a pattern density of the second region.

When performing the exposure process using a light source providing the first region and the second region with lights having similar, or equivalent, resolutions, bridges may be form between the photoresist patterns in the first region due to a pattern density of the first region possibly being larger than a pattern density of the second region.

To suppress the bridges in the first region, a light source capable of enhancing a resolution of a light incident on the first region may be used. When using the enhancing light source, the resolution of the light incident on the first region may be larger than a resolution of a light incident on the second region.

When the pattern density of the first region is smaller than the pattern density of the second region, bridges may form in the second region instead of the first region.

To suppress the bridges in the second region, the difference in pattern density between the first region and second regions may be decreased by increasing critical dimensions between the photoresist patterns in the second region.

When the critical dimensions between the photoresist patterns in the second region increase, critical dimensions of patterns formed under the second region may also increase due to the photoresist pattern structure being used as an etching mask during an etching process to form the patterns.

### SUMMARY OF THE INVENTION

Example embodiments of the present invention relate to a method of manufacturing a pattern structure and a method of forming a trench using the method of manufacturing the pattern structure. Other example embodiments of the present invention relate to a method of manufacturing a pattern structure formed by etching a layer and a method of forming a trench by using the same.

Example embodiments of the present invention provide a method of manufacturing a pattern structure, the method being capable of more efficiently reducing a critical dimension of the pattern structure.

In accordance with example embodiments of the present invention, there is provided a method of manufacturing a pattern structure. In the method, a mask pattern structure may be formed on a layer. The mask pattern structure may have mask patterns spaced apart from one another. The mask pattern structure may be divided into a first region having a first pattern density and a second region having a second pattern density higher than the first pattern density. The layer may be etched using the mask pattern structure as an etching mask to form first sidewalls positioned under the first region and second sidewalls positioned under the second region. The first sidewalls may have a first profile that may be vertical. The second sidewalls may have a second profile of which an interval between the second sidewalls may become narrower toward lower portions of the second sidewalls.

In accordance with other example embodiments of the present invention, there is provided a method of manufacturing a pattern structure. In the method, a photoresist film may be formed on a layer. An exposure process may be performed on the photoresist film. A development process may be performed on the photoresist film to form a photoresist pattern structure having photoresist patterns spaced apart from one another. The photoresist pattern structure may be divided into a first region having a first pattern density and a second region having a second pattern density lower than the first pattern density. The layer may be etched using the photoresist pattern structure as an etching mask to form patterns having first sidewalls positioned under the first region and second sidewalls positioned under the second region. The first sidewalls may have a first profile that may be vertical. The second sidewalls may have a second profile of which an interval between the second sidewalls may become narrower toward lower portions of the second sidewalls.

In accordance with yet other example embodiments of the present invention, there is provided a method of forming a trench. In the method, after forming a hard mask layer on a substrate, a photoresist film may be formed on the hard mask layer. An exposure process may be performed on the photoresist film. A development process may be performed on the photoresist film to form a photoresist pattern structure having photoresist patterns spaced apart from one another. The photoresist pattern structure may be divided into a first region having a first pattern density and a second region having a second pattern density lower than the first pattern density. The hard mask layer may be etched using the photoresist pattern structure as a first etching mask to form hard mask pattern structure having hard mask patterns. The hard mask patterns may have first sidewall positioned under the first region and second sidewalls positioned under the second region. The first sidewalls may have a first profile that may be vertical. The second sidewalls may have a second profile of which an interval between the hard mask patterns may become narrower toward lower portions of the hard mask patterns. The substrate may be etched using the hard mask pattern structure as a second etching mask.

According to example embodiments of the present invention, the formation of bridges between the photoresist patterns may be more suppressed. In addition, a critical dimension may be more efficiently reduced using patterns having a profile of which an interval between the patterns adjacent to each other becomes narrower toward lower portions of the patterns.

### BRIEF DESCRIPTION OF THE DRAWINGS

Example embodiments of the present invention will become readily apparent by reference to the following detailed description when considering in conjunction with the accompanying drawings. FIGS. 1 to 9 represent non-limiting example embodiments of the present invention as described herein.

FIGS. 1 to 3 are cross-sectional views illustrating a method of manufacturing a pattern structure in accordance with example embodiments of the present invention;

FIGS. 4, 9 and 10 are cross-sectional views illustrating a method of forming a trench in accordance with example embodiments of the present invention;

FIG. 6 is a plan view illustrating a photoresist pattern having first bridges in accordance with example embodiments of the present invention;

FIG. 7 is a plan view illustrating a photoresist pattern having second bridges in accordance with example embodiments of the present invention; and

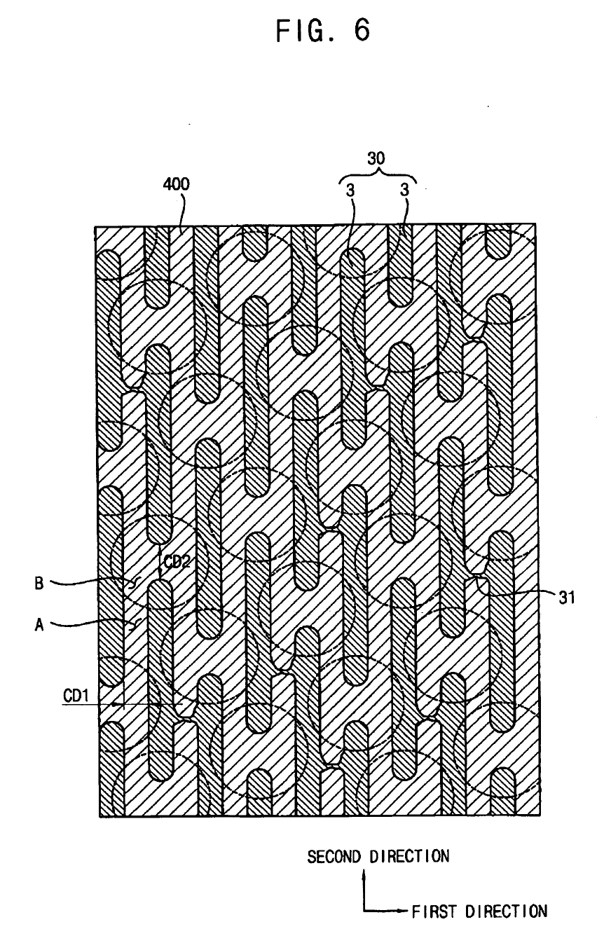

FIGS. 5, 8 and 11 are plan views illustrating a method of forming the trench together with FIGS. 4, 9 and 10 in accordance with example embodiments of the present invention.

### DESCRIPTION OF EXAMPLE EMBODIMENTS

Example embodiments of the present invention will be described with reference to the accompanying drawings. The present invention may, however, be embodied in many different forms and should not be construed as limited to the example embodiments set forth herein. Rather, the example embodiments are provided so that disclosure of the present invention will be thorough and complete, and will fully convey the scope of the present invention to those skilled in the art. The principles and features of this invention may be employed in varied and numerous example embodiments without departing from the scope of the present invention. In the drawings, the size and relative sizes of layers and regions may be exaggerated for clarity. The drawings are not to scale. Like reference numerals refer to like elements throughout.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature of a device and are not intended to limit the scope of the present invention.

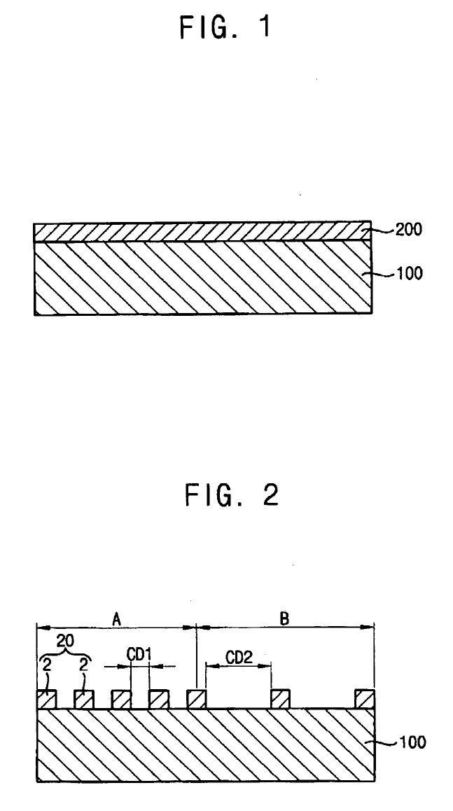

FIGS. 1 to 3 are cross-sectional views illustrating a method of manufacturing a pattern structure in accordance with example embodiments of the present invention.

Referring to FIG. 1, a mask layer 200 may be formed on a layer 100. The layer 100 may have a first etch rate in a pre-selected etching solution, the mask layer 200 may have a second etch rate lesser than the first etch rate of the layer 100 in the pre-selected etching solution. The mask layer 200 may have an etching selectively with respect to the layer 100.

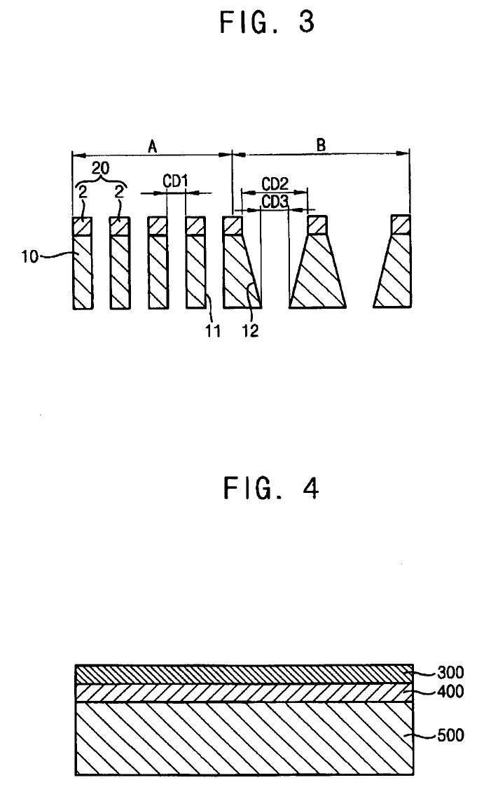

Referring to FIG. 2, a patterning process (e.g., a photolithography process) may be performed on the mask layer 200 in order that a mask pattern structure 20 having mask patterns 2 may be formed. The mask pattern structure 20 may be divided into a first region A and a second region B. The first region A and the second region B may have a first pattern density and a second pattern density, respectively. The second pattern density may be smaller than the first pattern density.

The mask patterns 2 in the first region A may be spaced apart from one another by a first critical dimension CD1. The mask patterns 2 in the second region B may be spaced apart from one another by a second critical dimension CD2. The second critical dimension CD2 may be larger than the first critical dimension CD1.

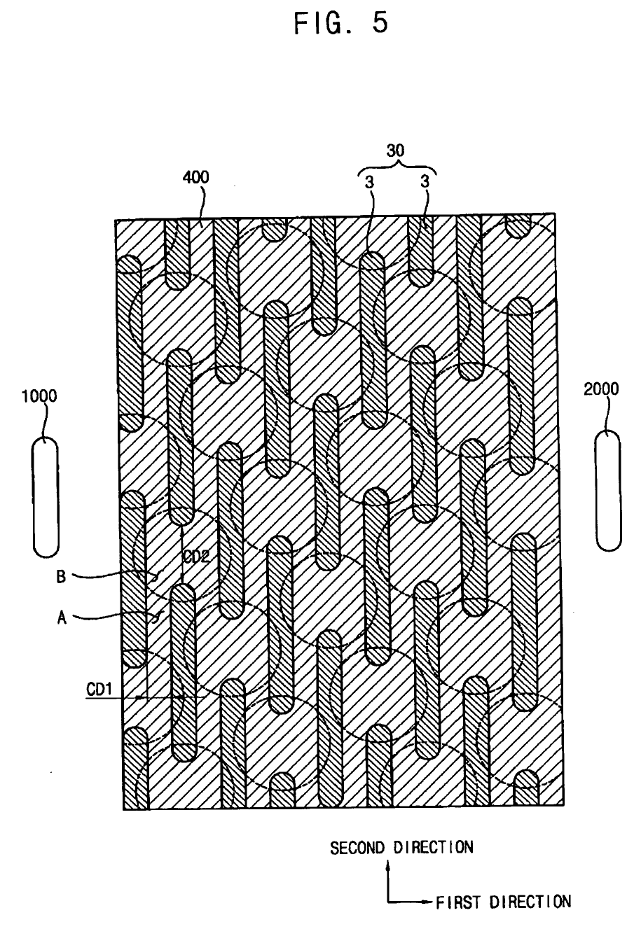

Referring to FIG. 3, the layer 100 may be etched using the mask pattern structure 20 as an etching mask so that a pattern structure 10 may be formed. An angular loading effect may not be generated at a first portion of the layer 100, the first portion being positioned under the first region A. A first sidewall 11 positioned under the first region A may have a first profile that may be substantially vertical.

The angular loading effect may be generated at a second portion of the layer 100, the second portion being positioned under the second region B. A second sidewall 12 positioned under the second region B may have a positive slope. The second sidewall 12 may have a second profile of which an interval between the second sidewalls 12 may become narrower toward lower portions of the second sidewalls 12.

Upper portions of the second sidewalls 12 may be spaced apart from one another by the second critical dimension CD2. Due to the second profile, the lower portions of the second sidewalls 12 may be spaced apart from one another by a third critical dimension CD3 smaller than the second critical dimension CD2.

The angular loading effect may be generated when performing an etching process for manufacturing a semiconductor device. A frequency and/or an extent of the angular loading effect may be determined by adjusting process conditions (e.g., etching temperature, etching time, etching solution, etc.). Generation of the angular loading effect may relate to an etch rate. The etch rate may vary according to a density of mask patterns included in a mask pattern structure formed on a layer.

When an interval between the mask patterns on the layer is large, an area of a portion of the layer exposed between the mask patterns may be large. The etching solution may more efficiently etch the portion of the layer exposed between the mask patterns. Also, etching byproducts may be more efficiently removed from the portion of the layer. Thus, an etch rate of the layer may increase. An increase in the etching rate may generate the angular loading effect.

When an interval between the mask patterns on the layer is small, the area of the portion of the layer exposed between the mask patterns may be smaller. The etching solution may not sufficiently etch the portion of the layer exposed between the mask patterns. Etching byproducts may not be more efficiently removed from the portion of the layer. Thus, the etch rate of the layer may decrease. The angular loading effect may not be generated.

In general, the angular loading effect may be a kind of defect that should be suppressed. However, in the present invention, the angular loading effect is intentionally generated in order to form the second sidewall 12 having the second profile of which the interval between the second sidewalls 12 may become narrower toward the lower portions of the second sidewalls 12.

FIGS. 4, 9 and 10 are cross-sectional views illustrating a method of forming a trench in accordance with example embodiments of the present invention. FIGS. 5, 8 and 11 are plan views illustrating a method of forming the trench together with FIGS. 4, 9 and 10.

Referring to FIG. 4, a hard mask layer 400 may be formed on a substrate 500. A planarization process may be performed on a surface portion of the hard mask layer 400 in order that a margin of a succeeding photolithography process may increase. A photoresist film 300 may be formed on the hard mask layer 400.

The substrate 500 may be a silicon substrate or a silicon-on-insulator (SOI) substrate. An etch rate of the hard mask layer 400 in a predetermined etching solution may be lesser than an etch rate of the substrate 500. The hard mask layer 400 has an etching selectivity with respect to the substrate 500 in the predetermined etching solution. For example, the hard mask layer 400 may be formed using a silicon nitride such as silicon oxynitride (SiON).

Referring to FIG. 5, a photolithography process may be performed on the photoresist film 300 so that photoresist patterns 3 may be formed. An exposure process using a first light source 1000 and a second light source 2000 may be performed on the photoresist film 300 so that the photoresist film 300 may be more selectively exposed to light. The first and second light sources 1000 and 2000 may be positioned above the photoresist patterns 3. The first and second light sources 1000 and 2000 may be substantially symmetric with respect to the photoresist pattern 3 in a first direction.

A development process may be performed on the photoresist film 300 so that a photoresist pattern structure 30, which may include the photoresist patterns 3 that may be spaced apart from one another, may be formed. The hard mask layer 400 may be partially exposed through the photoresist pattern structure 30.

The photoresist pattern structure 30 may be divided into a first region A and a second region B. The first region A may have a first pattern density. The second region B may have a second pattern density lower than the first pattern density.

The photoresist pattern 3 may extend in a second direction substantially perpendicular to the first direction. Each of the photoresist patterns 3 may have a bar shape. The photoresist patterns 3 may be substantially parallel with one another.

The photoresist patterns 3 in the first region A may be spaced apart from one another by a first critical dimension CD1 in the first direction. The photoresist patterns 3 in the second region B may be spaced apart from one another by a second critical dimension CD2 in the second direction. The second critical dimension CD2 may be larger than the first critical dimension CD1.

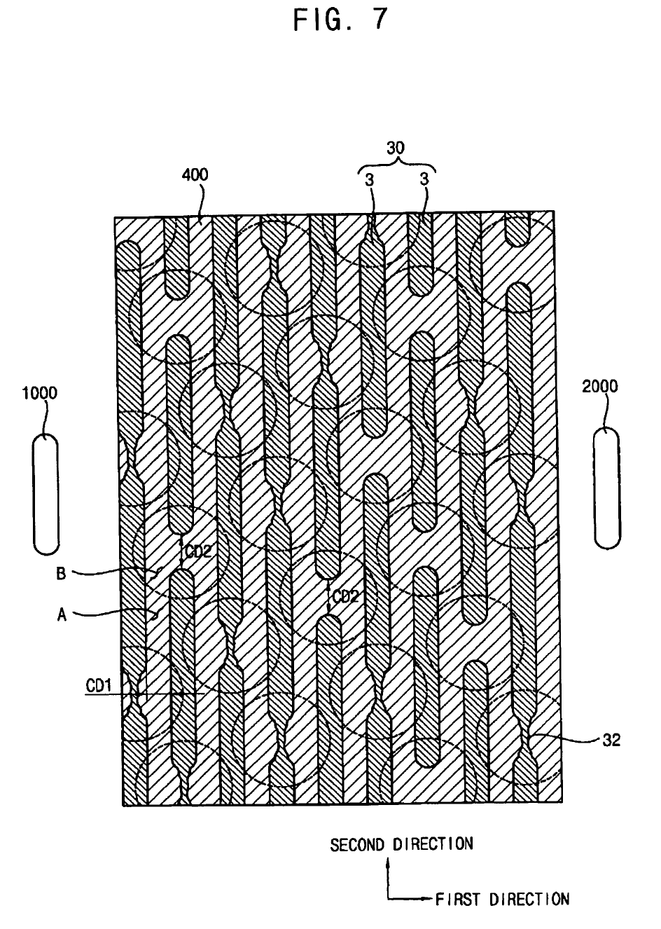

If a conventional light source providing the first region A and the second region B with lights having the same resolutions is employed in the exposure process performed on the photoresist film 300 instead of the first and second light sources 1000 and 2000, a first bridge 31 (see FIG. 6) extending in the first direction may be formed between the photoresist patterns 3 that are adjacent to each other in the first region A. This is because the first critical dimension CD1 is smaller than the second critical dimension CD2.

FIG. 6 is a plane view illustrating a photoresist pattern having a first bridge.

Referring to FIG. 6, a first bridge 31 extending in the first direction may be formed between the photoresist patterns 3 adjacent to each other in the first region A. A portion of the hard mask layer 400 exposed between the photoresist patterns 3 may be covered by the first bridge 31.

Referring again to FIG. 5, in the present invention, the exposure process may be performed on the photoresist film 300 by using the first and second light sources 1000 and 2000. When performing the exposure process using the first and second light sources 1000 and 2000, a resolution of light, incident on the photoresist film 300 in the first direction, may increase. Lights, having larger resolutions, may be incident on the first region A. Lights, having smaller resolutions, may be incident on the second region B. Thus, the first bridge 31 may not be formed in the first region A. That is, the first and second light sources 1000 and 2000 are employed in the exposure process in order to suppress the first bridge 31.

As described above, when the first and second light sources 1000 and 2000 are employed in the exposure process, the resolution of light incident on the photoresist film 300 in the first direction increases. When the resolution of light incident on the photoresist film 300 in the first direction increases, the resolution of light incident on the photoresist film 300 in the second direction may relatively decrease. That is, lights having relatively large resolutions may be incident on the first region A. However, lights having relatively small resolutions may be incident on the second region B.

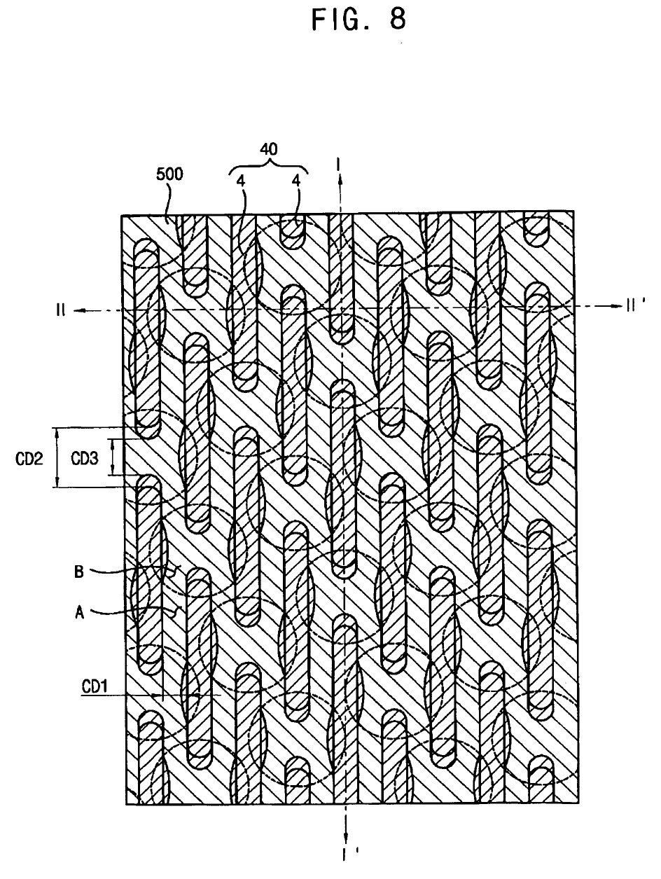

Thus, if a difference between the first pattern density of the first region A and the second pattern density of the second region B is relatively small, a second bridge 32 (See FIG. 7) extending in the second direction may be formed between the photoresist patterns 3 adjacent to each other in the second region B by a decrease in the solution of light incident on the photoresist film 300 in the first direction.

That is, if a difference between the first critical dimension CD1 and the second critical dimension CD2 is relatively small, the second bridge 32 (See FIG. 7) may be formed.

FIG. 7 is a plan view illustrating photoresist pattern having the second bridge.

Referring to FIG. 7, the first critical dimension CD1 may be about 60 nm to about 80 nm. The second critical dimension CD2 may be about 80 nm to about 95 nm. The difference between the first critical dimension CD1 and the second critical dimension CD2 may be small. Thus, a second bridge 32, extending in the second direction, may form between the photoresist patterns 3 adjacent to each other in the second region B.

When the second bridge 32 is formed, a portion of the hard mask layer 400, exposed between the photoresist patterns 3, may be covered by the second bridge 32.

Referring again to FIG. 5, the first critical dimension CD1 may be about 60 nm to about 80 nm. The second critical dimension may be about 80 nm to about 95 nm. Thus, the difference between the first critical dimension CD1 and the second critical dimension CD2 may be large. The second bridge 32 may not be formed in the second region B even though the exposure process is performed using the first light source 1000 and the second light source 2000 in order to suppress the first bridge 31 in the first region A.

When the first critical dimension CD1 is below about 60 nm, the first bridge 31 may be formed even though the exposure process is performed using the first light source 1000 and the second light source 2000. When the first critical dimension CD1 is above about 80 nm, a size of a semiconductor device, including the pattern structure, may increase. Thus, the first critical dimension CD1 may be about 60 nm to about 80 nm. For example, the first critical dimension CD1 may be about 70 nm.

When the second critical dimension CD2 is below about 95 nm, the difference between the first critical dimension CD1 and the second critical dimension CD2 may be small. Thus, when the exposure process is performed using the first light source 1000 and the second light source 2000 in order to suppress the first bridge 31, the second bridge 32 may be formed. On the other hand, in case that the second critical dimension CD2 is above about 105 nm, the semiconductor device, including the pattern structure, may increase. Thus, the second critical dimension CD2 may be about 95 nm to about 105 nm. For example, the second critical dimension CD2 may be about 100 nm.

Referring to FIG. 8, the hard mask layer 400 may be etched using the photoresist pattern structure 30 as an etching mask such that a hard mask pattern structure 40 having hard mask patterns 4, spaced apart from one another, may be formed on the substrate 500. The photoresist pattern structure 30 may be removed by an ashing process and/or a stripping process.

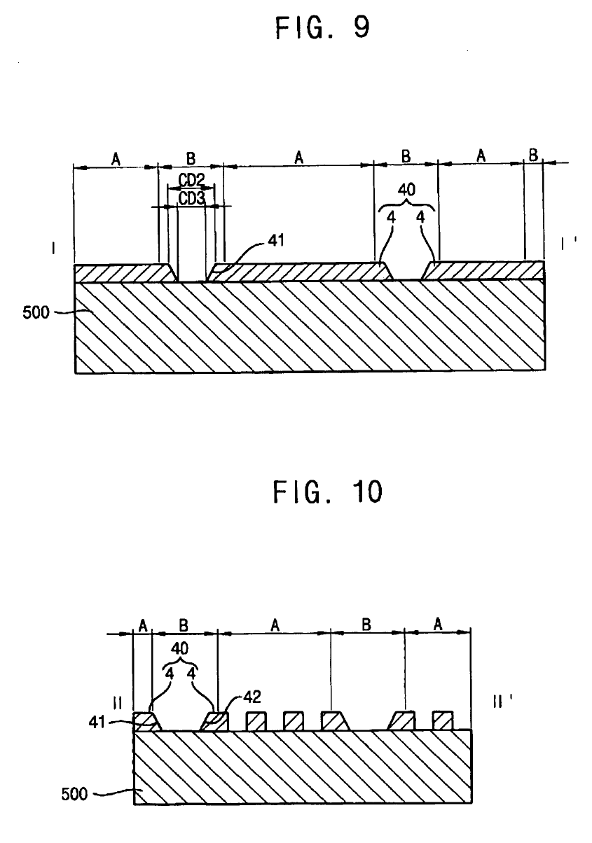

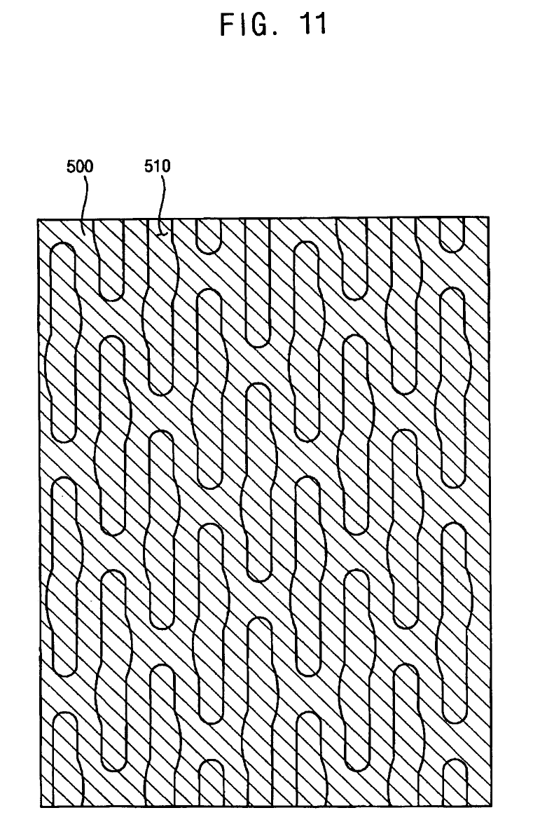

Because the first region A of the photoresist pattern structure 30 has a higher pattern density, an angular loading effect may not be generated under the first region A. Thus, a first sidewall 41 (see FIGS. 9 and 10) positioned under the first region A of the hard mask patterns 4 may have a first profile that may be substantially vertical.

Because the second region B of the photoresist pattern structure 30 has a lower pattern density, the angular loading effect may be generated under the second region B. Thus, a second sidewall 42 (see FIGS. 9 and 10) positioned under the second region B of the hard mask patterns 4 may have a second profile with a positive slope. That is, the second sidewall 42 may have the second profile of which an interval between the second sidewalls 42 becomes narrower toward lower portions of the sidewalls 42.

Upper portions of the second sidewalls 42 positioned under the second region B may be spaced apart from one another by the second critical dimension CD2. Due to the positive slope of the second sidewalls 42, lower portions of the second sidewalls 42 positioned under the second region B, may be spaced apart from one another by the third critical dimension CD3. The third critical dimension CD3 may be smaller than the second critical dimension CD2.

When the photoresist patterns 3 are spaced apart from one another in the second direction by the second critical dimension CD2 of about 95 nm to about 105 nm, the second bridge 32, formed due to the first and second light sources 1000 and 2000, may be more efficiently suppressed. The lower portions of the second sidewalls 42 may be spaced apart from one another by the third critical dimension CD3 smaller than the second critical dimension CD2 by virtue of the angular loading effect.

A margin of the photolithography process may increase. An interval between active regions, formed under the hard mask patterns 4, may decrease. An area of the active region may increase.

FIG. 9 is a cross-sectional view taken along line I-I′ in FIG. 8. FIG. 10 is a cross-sectional view taken along line II-II′ in FIG. 8.

Referring to FIGS. 9 and 10, the first sidewall 41 of the hard mask pattern 4, positioned under the first region A, may have the first profile that may be substantially vertical, due to the angular loading effect not being generated under the first region A.

The second sidewall 42 of the hard mask pattern 4, positioned below the second region B, may have a positive slope. An interval between the second sidewalls 42 may become narrower toward lower portions of the second sidewalls 42, due to the generation of the loading effect under the second region B.

Referring to FIG. 11, the substrate 500 may be etched using the hard mask pattern structure 40 as a second etching mask so that a trench 510 may be formed in a surface of the substrate 500. The hard mask pattern structure 40 may be removed.

According to the present invention, a bridge connected between the photoresist patterns may be more suppressed. In addition, a critical dimension may be more efficiently reduced using patterns having a profile of which an interval between the patterns adjacent to each other becomes narrower toward lower portions of the patterns.

The foregoing is illustrative of the example embodiments of the present invention and is not to be construed as limiting thereof. Although a few example embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the embodiments of the present invention and is not to be construed as limited to the example embodiments disclosed, and that modifications to the disclosed example embodiments, as well as other example embodiments, are intended to be included within the scope of the appended claims. The invention is defined by the following claims, with equivalents of the claims to be included therein.

What is claimed is:

1. A method of manufacturing a pattern structure, comprising:
forming a mask pattern structure on a layer, the mask pattern structure having mask patterns spaced apart from one another, the mask pattern structure being divided into a first region having a first pattern density and a second region having a second pattern density substantially higher than the first pattern density; and etching the layer by using the mask pattern structure as an etching mask to form first sidewalls positioned under the first region and second sidewalls positioned under the second region, the first sidewall having a first profile that is substantially vertical, the second sidewall having a second profile of which an interval between the second sidewalls becomes narrower toward lower portions of the second sidewalls.

2. The method of claim 1, wherein the second profile is due to an angular loading effect.

3. The method of claim 1, wherein the mask pattern structure has an etching selectivity with respect to the layer.

4. The method of claim 1, wherein the mask patterns adjacent to each other are spaced apart from each other in a first direction by a first critical dimension, the mask patterns adjacent to each other being spaced apart from each other in a second direction substantially perpendicular to the first direction by a second critical dimension substantially larger than the first critical dimension.

5. The method of claim 4, wherein the first critical dimension is about 60 nm to about 80 nm, and the second critical dimension is about 95 nm to about 105 nm.

6. A method of manufacturing a pattern structure, the method comprising:
forming a photoresist film on a layer;
performing an exposure process on the photoresist film;
performing a development process on the photoresist film to form a photoresist pattern structure having photoresist patterns spaced apart from one another, the photoresist pattern structure being divided into a first region having a first pattern density and a second region having a second pattern density substantially smaller than the first pattern density; and
etching the layer by using the photoresist pattern structure as an etching mask to form patterns having first sidewalls positioned under the first region and second sidewalls positioned under the second region, the first sidewall having a first profile that is substantially vertical, the second sidewall having a second profile of which an interval between the second sidewalls becomes narrower toward lower portions of the second sidewalls.

7. The method of claim 6, the second profile is due to an angular loading effect.

8. The method of claim 6, the photoresist pattern structure has an etching selectivity with respect to the layer.

9. The method of claim 6, wherein the exposure process is performed using first light incident on the first region and second light incident on the second region, a resolution of the second light being substantially lower than that of the first light.

10. The method of claim 6, wherein the photoresist patterns adjacent to each other are spaced apart from each other in a first direction by a first critical dimension, the photoresist patterns adjacent to each other are spaced apart from each other in a second direction substantially perpendicular to the first direction by a second critical dimension substantially larger than the first critical dimension.

11. The method of claim 10, wherein the first critical dimension is about 60 nm to about 80 nm, and the second critical dimension being about 95 nm to about 105 nm.

12. The method of claim 10, wherein the exposure process is performed using first and second light sources, the first and second light sources being positioned above the photoresist film, the first and second light sources being substantially symmetric with respect to the photoresist pattern in the second direction.

13. The method of claim 10, wherein the exposure process is performed using first light incident on the first region and second light incident on the second region, a resolution of the second light being substantially lower than that of the first light.

14. A method of forming a trench, the method comprising:
forming a hard mask layer on a substrate;
forming a photoresist film on the hard mask layer;
performing an exposure process on the photoresist film;
performing a development process on the photoresist film to form a photoresist pattern structure having photoresist patterns spaced apart from one another, the photoresist pattern structure being divided into a first region having a first pattern density and a second region having a second pattern density substantially lower than the first pattern density;
etching the hard mask layer by using the photoresist pattern structure as a first etching mask to form a hard mask pattern structure having hard mask patterns, the hard mask patterns having first sidewalls positioned under the first region and second sidewalls positioned under the second region, the first sidewall having a first profile that is substantially vertical, the second sidewall having a second profile of which an interval between the hard mask patterns becomes narrower toward lower portions of the hard mask patterns; and
etching the substrate by using the hard mask pattern structure as a second etching mask.

15. The method of claim 14, wherein the second profile is due to an angular loading effect.

16. The method of claim 14, wherein the hard mask layer has an etching selectivity with respect to the substrate.

17. The method of claim 14, wherein the hard mask layer includes silicon nitride.

18. The method of claim 14, wherein the photoresist patterns adjacent to each other are spaced apart from each other in a first direction by a first critical dimension, the photoresist patterns adjacent to each other are spaced apart from each other in a second direction substantially perpendicular to the first direction by a second critical dimension substantially larger than the first critical dimension.

19. The method of claim 18, the first critical dimension is about 60 nm to about 80 nm, and the second critical dimension is about 95 nm to about 105 nm.

20. The method of claim 18, wherein the exposure process is performed using first and second light sources, the first and second light sources being positioned above the photoresist film, the first and second light sources being substantially symmetric with respect to the photoresist pattern.

21. The method of claim 18, wherein the exposure process is performed using first light incident on the first region and second light incident on the second region, a resolution of the second light being substantially lower than that of the first lights.
